(19) United States
(12) Patent Application Publication
(10) Pub. No.: US 2009/0085716 A1
(43) Pub. Date: Apr. 2, 2009

(54) SEMICONDUCTOR DEVICE AND METHOD OF FABRICATING THE SAME

(76) Inventor: Jung-Ho Kim, Dongdaemun-gu (KR)

Correspondence Address: SHERR & VAUGHN, PLLC, 620 HERNDON PARKWAY, SUITE 200, HERNDON, VA, 20170, US

(21) Appl. No.: 12/241,114

(22) Filed: Sep. 30, 2008

(30) Foreign Application Priority Data
Oct. 1, 2007 (KR) 10-2007-0098690

(51) Int. Cl. H01C 1/14; H01C 17/28; H01L 21/60

(52) U.S. Cl. 338/325; 29/621; 438/597; 257/E21.506

(57) ABSTRACT

A semiconductor device and a method for manufacturing the same that includes terminal patterns and resistor patterns disposed between and electrically connected to the terminal patterns. The resistor patterns have an electrical resistance higher than the electrical resistance of the terminal patterns and also have a width greater than a width of the terminal patterns

The present application claims priority under 35 U.S.C. 119 to Korean Patent Application No. 10-2007-0098690, (filed on Oct. 1, 2007), which is hereby incorporated by reference in its entirety.

### BACKGROUND

Devices such as a liquid crystal display (LCD) panel require a plurality of output terminals to output a voltage. In order to implement this, a driver IC chip including a semiconductor device capable of reducing deviation between voltages output from the output terminals may be provided.

### SUMMARY

Embodiments relate to semiconductor devices that receive a predetermined voltage and minimizes variation of performance such that the semiconductor devices may have substantially the same performance.

Embodiments relate to a semiconductor device that may include at least one of the following: terminal patterns disposed in a row and spaced apart from each other, and resistor patterns interposed between the terminal patterns and electrically connected to the terminal patterns. The resistor patterns have a resistance higher than the resistance of the terminal patterns and have a width greater than the width of the terminal patterns.

In accordance with embodiments, the terminal patterns may be composed of silicide while the resistor patterns may be composed of polysilicon. In accordance with embodiments, the terminal patterns are aligned in an alternating manner with respect to the resistor patterns such that two opposite ends of the terminal patterns receive voltages having a predetermined potential difference, and the terminal patterns output a dropped voltage. In accordance with embodiments, the semiconductor device includes a protective layer formed on and/or over and covering the terminal patterns and the resistor patterns.

Embodiments relate to a semiconductor device that may include at least one of the following: a first terminal pattern, a first resistor pattern electrically connected to the first terminal pattern and having a width greater than the width of the first terminal pattern, a second terminal pattern electrically connected to the first resistor pattern and having a width smaller than the width of the first resistor pattern, a second resistor pattern electrically connected to the second terminal pattern and having a width greater than the width of the second terminal pattern, and a third terminal pattern electrically connected to the second resistor pattern and having a width smaller than the width of the second resistor pattern.

Embodiments relate to method of manufacturing a semiconductor device that may include at least one of the following steps: sequentially forming a first insulating layer, a polysilicon layer and a second insulating layer over a semiconductor substrate; and then forming second insulating patterns exposing portions of the uppermost surface of the polysilicon layer; and then forming a metal layer over the second insulating layer patterns and the exposed portions of the polysilicon layer; and then simultaneously forming terminal patterns at the exposed portions of the polysilion layer and resistor patterns at non-exposed portions of the polysilicon layer such that the terminal patterns are electrically connected to the resistor patterns. In accordance with embodiments, the resistor patterns have an electrical resistance higher than the electrical resistance of the terminal patterns and also have a width greater than a width of the terminal patterns.

In the semiconductor device in accordance with embodiments, even if an error occurs longitudinally in the resistor patterns, the resistor patterns have a width greater than that of the terminal patterns, so that performance variation of the semiconductor device can be minimized.

### DRAWINGS

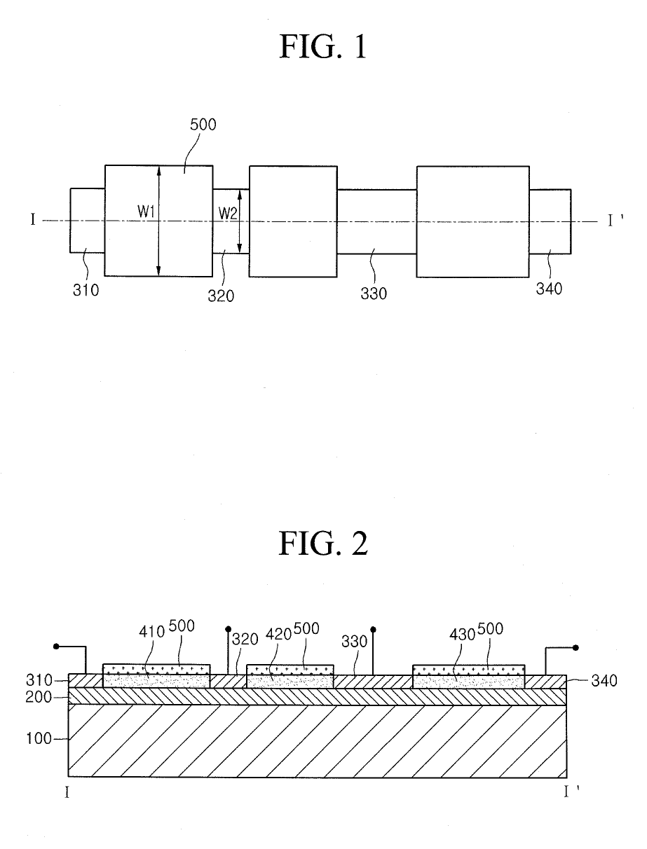

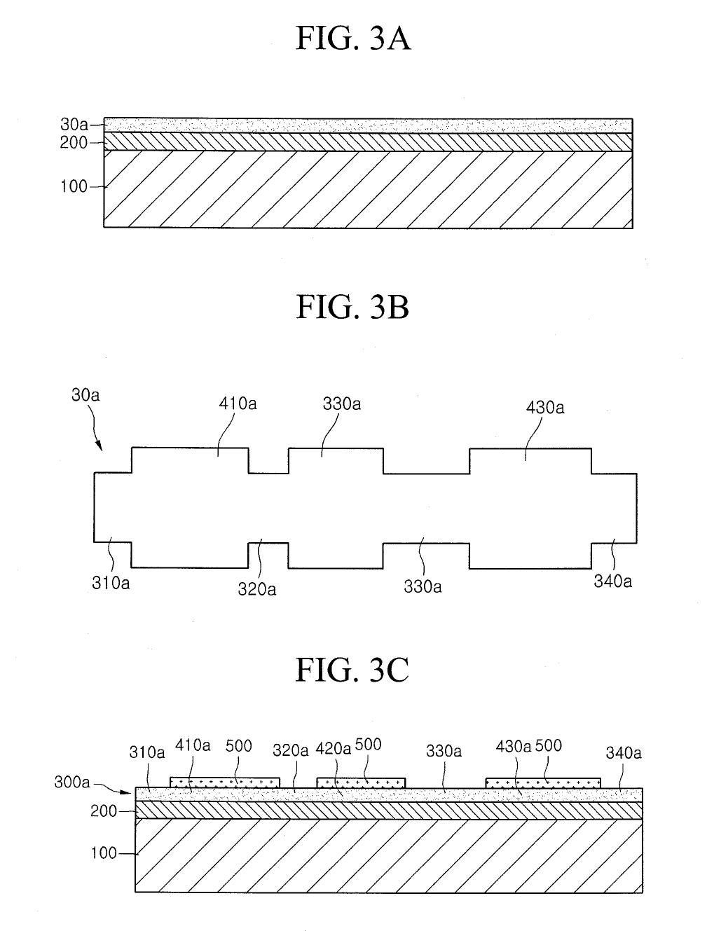

Example FIGS. 1 and 2 illustrate terminal patterns and resistor patterns in accordance with embodiments.

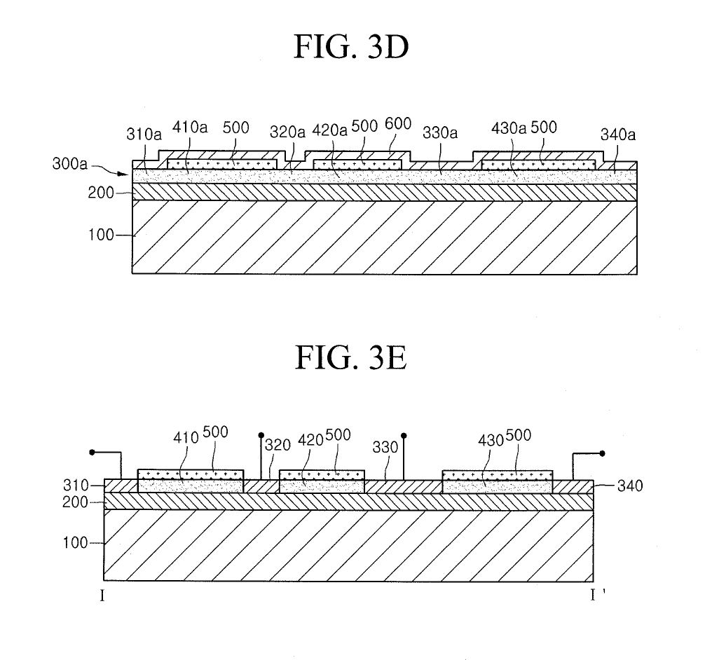

Example FIGS. 3A to 3E illustrate the manufacturing process of a semiconductor device in accordance with embodiments.

### DESCRIPTION

Example FIG. 1 is a plan view showing terminal patterns and resistor patterns in accordance with embodiments, and example FIG. 2 is a sectional view taken along line I-I′ of example FIG. 1 and illustrates a semiconductor substrate, an insulating layer, and a protective layer.

As illustrated in example FIGS. 1 and 2, a semiconductor device in accordance with embodiments includes semiconductor substrate 100, insulating layer 200, a plurality of terminal patterns 310, 320, 330, and 340, a plurality of resistor patterns 410, 420, and 430, and protective layer 500. The semiconductor substrate 100 may have a rectangular-type shape, but is not limited to such a geometric shape. Semiconductor substrate 100 may be composed of amorphous silicon. Insulating layer 200 is formed on and/or over semiconductor substrate 100. Insulating layer 200 may be formed on and/or over the entire surface of semiconductor substrate 100 in order to insulate semiconductor substrate 100. Insulating layer 200 may be composed of silicon oxide (SiOx).

Terminal patterns 310, 320, 330, and 340 are disposed in a row spaced apart on and/or over insulating layer 200. The terminal patterns may include first terminal pattern 310, second terminal pattern 320, third terminal pattern 330 and fourth terminal pattern 340. First terminal pattern 310, second terminal pattern 320, third terminal pattern 330 and fourth terminal pattern 340 may each be composed of silicide, etc. Resistor patterns 410, 420, and 430 are provided on and/or over insulating layer 200 and interposed in the spaces between first terminal pattern 310, second terminal pattern 320, third terminal pattern 330 and fourth terminal pattern 340. For example, resistor patterns 410, 420, and 430 are aligned in an alternating pattern with respect to terminal patterns 310, 320, 330, and 340. The resistor patterns may include first resistor pattern 410, second resistor pattern 420 and third resistor pattern 430. First resistor pattern 410, second resistor pattern 420 and third resistor pattern 430 may each be composed of polysilicon. Resistor patterns 410, 420, and 430 are connected to the terminal patterns 310, 320, 330, and 340 to form an electrical connection. Accordingly, resistor patterns 410, 420, and 430 are electrically connected to terminal patterns 310, 320, 330, and 340. For instance, first resistor pattern 410 is connected to first terminal pattern 310, second terminal pattern 320 is connected to first resistor pattern 410, second resistor pattern 420 is connected to second terminal pattern 320, third terminal pattern 330 is connected to second resistor pattern 430, third resistor pattern 430 is connected to third terminal pattern 330 and fourth terminal pattern 340 is connected to third resistor pattern 430. Resistor patterns 410, 420, and 430 have a resistance greater than that of terminal patterns 310, 320, 330, and 340. For example, since terminal patterns 310, 320, 330, and 340 include silicide and resistor patterns 410, 420, and 430 include polysilicon, resistor patterns 410, 420, and 430 have a resistance greater than that of terminal patterns 310, 320, 330, and 340. In addition, resistor patterns 410, 420, and 430 have a width greater than that of terminal patterns 310, 320, 330, and 340.

Protective layer 500 is provided on and/or over and covering the uppermost surface of resistor patterns 410, 420, and 430. Protective layer 500 may be composed of silicon nitride (SiNₓ). Protective layer 500 may serve to prevent resistor pattern 500 from being silicidated during formation of the semiconductor device.

A predetermined voltage is applied to first and fourth terminal patterns 310 and 340, and a voltage drop occurs due to the resistance of resistor patterns 410, 420, and 430, so that a predetermined voltage is output through terminal patterns 310, 320, 330, and 340. For example, fourth terminal pattern 340 may receive a ground potential and first terminal pattern 310 may receive a potential higher than the ground potential. Accordingly, a voltage drop occurs by first resistor pattern 410 so that a first voltage is output through second terminal pattern 320. In addition, a voltage drop occurs by first and second resistor patterns 410 and 420 so that a second voltage is output through third terminal pattern 330. Deviation may occur in the first and second voltages when comparing with other semiconductor devices. In other words, errors may occur in the first and second voltage due to a design error of resistor patterns 410, 420 and 430. Since resistor patterns 410, 420 and 430 have width W1 greater than width W2 of terminal patterns 310, 320, 330 and 340, even if errors occur in the length of resistor patterns 410, 420 and 430, an error in the semiconductor device is reduced as compared with a case in which width W1 of resistor patterns 410, 420 and 430 is identical to width W2 of terminal patterns 310, 320, 330 and 340.

For example, on the assumption that both width W1 of resistor patterns 410, 420 and 430 and width W2 of terminal patterns 310, 320, 330 and 340 are 10 μm, and the length of resistor patterns 410, 420 and 430 is 6 μm, if the length of resistor patterns 410, 420 and 430 is reduced to 5 μm (i.e., reduced by 1 μm), the resistance of resistor patterns 410, 420 and 430 is reduced from 600Ω to 500Ω (i.e., by 16.6%). In contrast, on the assumption that resistor patterns 410, 420 and 430 have width W1 of 20 μm and a length of 12 μm, and terminal patterns 310, 320, 330 and 340 have width W2 of 10 μm, if the length of resistor patterns 410, 420 and 430 is reduced to 11 μm (i.e., reduced by 1 μm), the resistance of resistor patterns 410, 420 and 430 is reduced from 600Ω to 532Ω (i.e., by 11.3%). In other words, when comparing the semiconductor device in accordance with embodiments with a semiconductor device including resistor patterns 410, 420 and 430 having the same width as that of terminal patterns 310, 320, 330 and 340, less errors occur in the semiconductor device in accordance with embodiments on the assumption that the same error occurs in the length of resistor patterns 410, 420 and 430 of the semiconductor devices.

Example FIGS. 3A to 3E are sectional views showing the manufacturing process of the semiconductor device according to the embodiment.

As illustrated in example FIG. 3A, silicon oxide or silicon nitride is deposited on and/or over semiconductor substrate 100, thereby forming insulating layer 200. Thereafter, a polysilicon layer is formed on and/or over insulating layer 200, and polysilicon pattern 300a is formed through a mask process in order to form terminal patterns and resistor patterns.

As illustrated in example FIG. 3B, in polysilicon pattern 300a, preliminary terminal patterns 310a, 320a, 330a, and 340a are connected to preliminary resistor patterns 410a, 420a, and 430a. Preliminary terminal patterns 310a, 320a, 330a, and 340a have a width smaller than the width of preliminary resistor patterns 410a, 420a, and 430a. In addition, preliminary terminal patterns 310a, 320a, 330a, and 340a are integrally formed with preliminary resistor patterns 410a, 420a, and 430a.

As illustrated in example FIG. 3C, protective layer 500 is formed on and/or over polysilicon pattern 300a by forming a nitride layer on and/or over and to cover polysilicon pattern 300a and then patterning the nitride layer through a mask process. Protective layer 500 covers preliminary resistor patterns 410a, 420a, and 430a and exposes portions of the uppermost surface of polysilicon pattern 300a where preliminary terminal patterns 310a, 320a, 330a, and 340a will be formed.

As illustrated in example FIG. 3D, metal layer 600 is formed on and/or over and to cover protective layer 500 and preliminary terminal patterns 310a, 320a, 330a, and 340a. Metal layer 600 may be composed of one of nickel (Ni), cobalt (Co) and titanium (Ti).

As illustrated in example FIG. 3E, after metal layer 600 is formed, semiconductor substrate 100 is subjected to heat treatment in order to silicide preliminary terminal patterns 310a, 320a, 330a, and 340a. Accordingly, terminal patterns 310, 320, 330, and 340 and resistor patterns 410, 420, and 430 are formed on and/or over insulating layer 200. Since the semiconductor device in accordance with embodiments includes resistor patterns 410, 420, and 430 having a width greater than that of terminal patterns 310, 320, 330, and 340, errors between voltages output from terminal patterns 310, 320, 330, and 340 can be reduced.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
terminal patterns disposed spaced apart over a semiconductor substrate; and
a resistor pattern interposed between the terminal patterns and electrically connected to the terminal patterns,
wherein each resistor pattern has an electrical resistance higher than the electrical resistance of the terminal patterns and also has a width greater than a width of the terminal patterns.

2. The semiconductor device of claim 1, wherein the terminal patterns include silicide.

3. The semiconductor device of claim 1, wherein each resistor pattern includes polysilicon.

4. The semiconductor device of claim 1, wherein the resistor patterns have a width in a range between approximately 0.8 μm to 1.0 μm.

5. The semiconductor device of claim 1, wherein the terminal patterns are aligned in an alternating pattern with respect to each resistor pattern.

6. The semiconductor device of claim 1, wherein two outermost ones of the terminal patterns receive voltages having predetermined potential difference such that the terminal patterns output a dropped voltage.

7. The semiconductor device of claim 1, further comprising a protective layer formed over and covering each resistor pattern.

8. A semiconductor device comprising:
a first terminal pattern;
a first resistor pattern electrically connected to the first terminal pattern, the first resistor pattern having a width greater than a width of the first terminal pattern;
a second terminal pattern electrically connected to the first resistor pattern, the second terminal pattern having a width smaller than the width of the first resistor pattern;
a second resistor pattern electrically connected to the second terminal pattern, the second resistor pattern having a width greater than the width of the second terminal pattern; and
a third terminal pattern electrically connected to the second resistor pattern, the third terminal pattern having a width smaller than the width of the second resistor pattern.

9. The semiconductor device of claim 8, wherein the first and second resistor patterns have each have an electrical resistance greater than an electrical resistance of the first, second and third terminal patterns.

10. The semiconductor device of claim 8, wherein the first and second resistor patterns include polysilicon and the first, second and third terminal patterns include silicide.

11. The semiconductor device of claim 8, wherein the second terminal pattern outputs a voltage dropped by the first resistor pattern, and the third terminal pattern outputs a voltage dropped by the first and second resistor patterns.

12. The semiconductor device of claim 8, further comprising:
a third resistor pattern electrically connected to the third terminal pattern, the third resistor pattern having a width greater than the width of the third terminal pattern; and
a fourth terminal pattern electrically connected to the third resistor pattern, the fourth terminal pattern having a width smaller than the width of the third resistor pattern.

13. A method of manufacturing a semiconductor device comprising:
sequentially forming a first insulating layer, a polysilicon layer and a second insulating layer over a semiconductor substrate; and then
forming second insulating patterns exposing portions of the uppermost surface of the polysilicon layer; and then
forming a metal layer over the second insulating layer patterns and the exposed portions of the polysilicon layer; and then
simultaneously forming terminal patterns at the exposed portions of the polysilion layer and resistor patterns at non-exposed portions of the polysilicon layer such that the terminal patterns are electrically connected to the resistor patterns,
wherein the resistor patterns have an electrical resistance higher than the electrical resistance of the terminal patterns and also have a width greater than a width of the terminal patterns.

14. The method of claim 13, wherein the first insulating layer comprises one of silicon oxide and silicon nitride.

15. The method of claim 13, wherein the second insulating layer comprises nitride.

16. The method of claim 13, wherein the metal layer comprises one of nickel (Ni), cobalt (Co) and titanium (Ti).

17. The method of claim 13, wherein the resistor patterns are formed under the second insulating layer patterns.

18. The method of claim 13, wherein simultaneously forming the terminal patterns and the resistor patterns comprises:
subjecting the entire semiconductor substrate to a heat treatment process.

19. The method of claim 18, wherein the terminal patterns comprises silicide.

20. The method of claim 13, wherein the resistor patterns are formed under the second insulating layer patterns.
